(19) United States
(12) Patent Application Publication
(10) Pub. No.: US 2017/0170395 A1
(43) Pub. Date: Jun. 15, 2017

(54) RESISTIVE SWITCHING MEMORY DEVICE USING BROWNMILLERITE-STRUCTURED MATERIAL

(71) Applicant: HANKUK UNIVERSITY OF FOREIGN STUDIES RESEARCH BUSINESS FOUNDATION, Gyeonggi-do (KR)

(72) Inventors: Chang-Uk Jung, Gyeonggi-do (KR); Bo-Hwa Lee, Gyeonggi-do (KR); Octolia Togibasa Tambunan, Gyeonggi-do (KR); Susant Kumar Acharya, Gyeonggi-do (KR)

(21) Appl. No.: 15/322,711

(22) PCT Filed: Aug. 14, 2015
(86) PCT No.: PCT/KR2015/008537

§ 371 Date: Dec. 28, 2016

(30) Foreign Application Priority Data
Sep. 18, 2014 (KR) 10-2014-0124495

(51) Int. Cl. H01L 45/00; G11C 13/00

(52) U.S. Cl. CPC H01L 45/147; H01L 45/1253; G11C 13/0097; H01L 45/1608

(57) ABSTRACT

A resistive switching memory device using a brownmillerite-structured material, the resistive switching memory device comprises a first electrode comprising an oxide electrode; a resistive switching unit that is disposed on the first electrode and comprises a thin-film of a brownmillerite structured oxide; and a second electrode that is disposed on the resistive switching unit. Furthermore, the resistive switching unit has a structure in which an octahedron structure layer and a tetrahedron structure layer are sequentially stacked.

### TECHNICAL FIELD

The present invention relates to a switching device and a method of fabricating the same, and more particularly, to a technique related to a resistive switching device using an insulator oxide.

### BACKGROUND ART

A resistive switching device has excellent non-volatile memory performance due to its low driving voltage and fast switching speed. In case of a conventional resistive switching device, a forming process for forming a filament as a conductive bridge constituting a conductive path in a sample at an initial stage is required. The forming process is a process for activating a device by applying a predetermined forming voltage to a resistance changing material so as to enable the device to be resistive switching. A filament conductive bridge formed in the forming process may interconnect a top electrode and a bottom electrode. A reset voltage is a voltage required to break the filament conductive bridge that have interconnected the top and bottom electrodes during the forming process. At this time, the reset voltage breaks only a portion of the filament conductive bridge. During an operation of a conventional resistive switching device, a forming voltage is generally higher than a reset voltage.

High forming voltages are often disadvantageous for device applications. A set voltage is a voltage required in order to re-connect a filament conductive bridge that has been partially broken by a reset voltage, wherein the set voltage may be also generally lower than the forming voltage. A resistive switching device is being researched as a nonvolatile device that is advantageous for higher density integration and higher speed than a conventional solid state drive (SSD). However, the resistive switching device bears a disadvantage of requiring a high voltage, and more particularly, a high forming voltage. When a forming voltage is high, consumption of electric power required for operating a device is increased, and switching characteristics as a storage device and inter-device reliability are also degraded. The Korean Patent Publication No. 10-2013-0080622 discloses a logic and a memory device based on a resistance change switching. However, the above-stated patent publication only discloses an implementation of driving various logic gates in a single device according to input conditions of electric signals and it is unable to resolve the problem of high forming voltage.

### DISCLOSURE OF THE INVENTION

### Technical Problem

The present invention provides a new resistive switching memory device capable of lowering a forming voltage than a reset voltage and a set voltage by using a brownmillerite-structured material in the resistive switching device for the first time.

### Technical Solution

According to an aspect of the present invention, there is provided a resistive switching memory device using a brownmillerite-structured material, the resistive switching memory device including a first electrode including an oxide electrode; a resistive switching unit that is disposed on the first electrode and comprises a thin film of a brownmillerite structured oxide; and a second electrode that is disposed on the resistive switching unit. Furthermore, the resistive switching unit has a brownmillerite structure in which an octahedron structure layer and a tetrahedron structure layer are sequentially stacked. In the resistive switching unit, a predetermined portion of the tetrahedron structure layer is transformed to an octahedron structure by an oxidization reaction which occurs by a forming voltage applied to between the first electrode and the second electrode, thereby forming a partial octahedron deformed region. The partial octahedron deformed region connects original octahedron structure layers adjacent to each other. As the octahedron structure layers are sequentially connected, a conductive path including the octahedron structure layers is formed between the first electrode and the second electrode, thereby switching the resistive switching unit into a low resistance state.

Furthermore, in the resistive switching unit having formed therein the partial octahedron deformed region, a partial tetrahedron deformed region is formed by a reduction reaction that occurs based on a reset voltage applied between the first electrode and the second electrode. A partial tetrahedron deformed region initially transformed to the partial octahedron deformed region due to a forming voltage is partially transformed to a tetrahedron structure layer and breaks a conductive path between the first electrode and the second electrode, thereby switching the resistive switching unit into a high resistance state. Furthermore, in the resistive switching unit having formed therein the partial tetrahedron deformed region due to a reset voltage, the partial tetrahedron deformed region is transformed to the partial octahedron deformed region through an oxidization reaction that occurs based on a set voltage applied between the first electrode and the second electrode. As a result, the resistive switching unit is transformed into a low resistance state.

In a resistive switching memory device using a brownmillerite-structured material according to the present invention, due to characteristics of a conductive path forming process using a redox reaction of a brownmillerite structure, a forming voltage is always lower than a set voltage. Furthermore, the resistive switching unit may include any one of strontium cobalt oxide (SrCoOₓ) and strontium ferrite (SrFeOₓ). Also, the resistive switching unit may include any of other oxides having a brownmillerite structure.

### Advantageous Effects

Since a conductive path is transformed within relatively short range in the process of formation of a conductive path using a brownmillerite-structured material, a resistive switching memory device according to the present invention may utilize a forming voltage lower than a set voltage. Therefore, a low-power device may be provided and switching characteristics and reliability of the device may be improved.

### BRIEF DESCRIPTION OF THE DRAWINGS

FIG. 1 is a schematic diagram showing a resistive switching device having brownmillerite structure according to an embodiment of the present invention;

FIG. 2 is a diagram showing a phase transition phenomenon of a resistive switching memory device using a brownmillerite-structured material according to an embodiment of the present invention;

FIG. 3 is a diagram showing an example of a resistive switching unit using SrCoOₓ of a resistive switching memory device that uses a brownmillerite-structured material according to an embodiment of the present invention;

FIG. 4 is a diagram showing a forming voltage, a set voltage, and a reset voltage of a resistive switching memory device using a brownmillerite-structured material according to an embodiment of the present invention;

FIG. 5 is a diagram for comparing a forming voltage and a set voltage of a resistive switching memory device using a brownmillerite-structured material according to an embodiment of the present invention with a forming voltage and a set voltage of a conventional resistive switching memory device; and

FIG. 6 is a diagram showing another example of a resistive switching memory device using a brownmillerite-structured material according to an embodiment of the present invention.

### MODE FOR CARRYING OUT THE INVENTION

Hereinafter, embodiments of the present invention will be described in detail with reference to the attached drawings. With respect to the terms in the various embodiments of the present invention, the general terms which are currently and widely used are selected in consideration of functions of structural elements in the various embodiments of the present invention. However, meanings of the terms may be changed according to intention, a judicial precedent, appearance of a new technology, and the like. In addition, in certain cases, a term which is not commonly used may be selected. In such a case, the meaning of the term will be described in detail at the corresponding part in the description of the present invention. Therefore, the terms used in the various embodiments of the present invention should be defined based on the meanings of the terms and the descriptions provided herein.

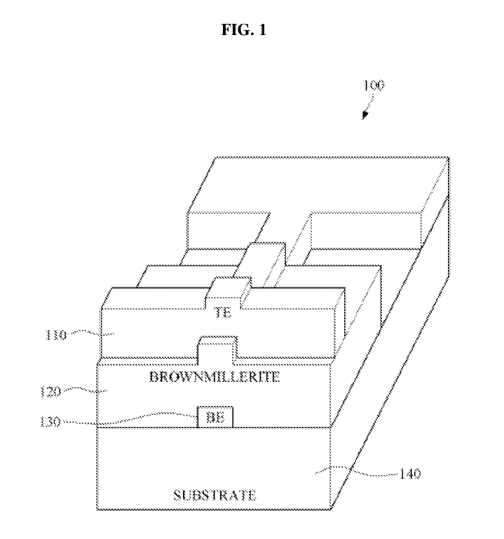

FIG. 1 is a schematic diagram showing a resistive switching device having brownmillerite structure according to an embodiment of the present invention.

Referring to FIG. 1, a resistive switching device 100 having brownmillerite structure according to the present invention may include a first electrode 130, a resistive switching unit 120, and a second electrode 110.

The first electrode 130 is a bottom electrode, and is disposed below the resistance variable layer 120. The second electrode 110 is a top electrode, and is disposed on other surface of the resistive switching unit 120. The first electrode 130 and the second electrode 110 sandwich the resistive switching unit 120 and apply voltages to the resistive switching unit 120 by using a voltage applied between the first electrode 130 and the second electrode 110. Furthermore, the resistive switching device 100 may further include a substrate 140 below other surface of the first electrode 130. The substrate may include a material utilized in conventional semiconductor devices. For example, the substrate 140 may include an oxide, a plastic, stainless steel, a Glove, vinyl, a fabric, etc., and may include a flexible material according to applications and purposes thereof.

Each of the first electrode 130 and the second electrode 110 may be formed to have a thin-film shape or a bar shape. The first electrode 130 is formed as an oxide electrode so as to supply oxygen atoms for redox process of the resistive switching unit 120. On the contrary, the second electrode 110 may include a conductive material which is generally utilized to form an electrode in the field of semiconductor technologies. Furthermore, the first electrode 130, which is the bottom electrode, and the second electrode 110 may be formed by patterning onto the resistive switching unit 120.

The resistive switching unit 120 may be formed into a thin-film disposed between the first electrode 130 and the second electrode 110. The resistive switching unit 120 includes a resistive switching material comprising a brownmillerite-structured oxide. A resistive switching device constituting the resistive switching unit 120 may be reversibly switched between a high resistance state and a low resistance state.

In case of conventional resistive switching devices, a filamentary conducting path for implementing a conductive path is formed by a forming process. The filamentary conducting path interconnects the first electrode 130 and the second electrode 110. A voltage required for the forming process is a forming voltage. Through the forming process, a device is activated as being a device with a low resistance state. In order to for switch the device from a low resistance state to a high resistance state by using a reset voltage, a reset process for breaking a portion of the filamentary conducting path is performed. Next, a set process for reconnecting the broken portion of the filamentary conducting path so as to switch the device from the high resistance state to the low resistance state by using a set voltage is performed. Through such the processes, bipolar resistive switching phenomenon occurs in a transition metal oxide due to ionic conduction or oxidation/reduction reaction. However, since a forming voltage is generally higher than a set voltage, the forming voltage itself is often disadvantageous for the device application.

The fundamental mechanism of resistive switching in the resistive switching unit 120, is divided into a filament mechanism and an interface mechanism. In the filament mechanism, a forming process creates a filamentary conducting path by a soft insulation breakdown process inside an insulator thin-film immediately after the insulator thin-film is deposited. After the forming process, a reset process in which a portion of the filamentary conducting path is broken, occurs. Then, a set process in which the broken portion is re-connected, and thus the first electrode 130 and the second electrode 110 are connected to each other via a conductive path, occurs by applying a predetermined voltage pulse to the insulator thin-film. In this regard, in a conventional Perovskite-structured resistive switching device, forming voltage for a forming process for creating a filamentary conducting path between a top electrode and a bottom electrode in order to interconnect the top electrode and the bottom electrode becomes higher than a set voltage for repairing only a broken portion.

However, the resistive switching memory device 100 using a brownmillerite-structured material has a forming voltage which is lower than a set voltage of it due to the characteristics of the brownmillerite structure. The brownmillerite structure of the resistive switching unit 120 is a structure that is formed with an octahedron structure layer and a tetrahedron structure alternately stacked layer by layer. The tetrahedron structure is formed by removing one oxygen atom from the octahedron structure. SrCoO_{2.5}, which is as an embodiment of the resistive switching unit 120, has a structure in which an octahedron structure layer and a tetrahedron structure layer are alternately stacked. When oxygen atom is additionally supplied to the material, the structure is transformed to have the Perovskite structure stacked only with the octahedron structure layer, wherein the Perovskite structure has electric conductivity. However, it is well known in the art that, when only one octahedron structure layer is present, the material loses its electrical conductivity. Depending on the material, it is necessary to successively stack about 3 to 10 octahedron structure layers (Perovskite structure) so as to exhibit electrical conductivity such as that of a metal. SrCoO_{2.5} may be reversibly transformed to SrCoO₃ having brownmillerite structure due to phase transition based on a redox reaction. When the phase transition occurs, an electrical transition between an insulator and a conductor also occurs.

The insulating brownmillerite structure of SrCoO_{2.5} may be switched from an initial insulator state to a low resistance state by injecting oxygen atom into one tetrahedron structure layer between octahedron structured layers that do not contact each other but are very closely adjacent to each other. Next, the first electrode 130 and the second electrode 110 may be completely connected to each other through an octahedron structure in a way of injecting one oxygen atom into the tetrahedron structure layer. In other words, it is possible to connect the first electrode 130 and the second electrode 110 fully as a conductive path is formed by sequentially forming such a short bridge.

In a conventional resistive switching device, it is necessary to form a filament between the first electrode 130 and the second electrode 110 at once. However, the resistance switching unit 120 using a brownmillerite-structured material builds a conductive path by transforming only a tetrahedron structure existing between the octahedron structures into an octahedron structure, thereby lowering a forming voltage. Furthermore, as the resistance switching unit 120 undergoes a reset process, a filamentary conducting path is partially broken. Since the phenomenon of the partial break of the filamentary conducting path is implanted due to heat generated by a current as well known in the art, octahedron structures existing in a local region in the filamentary conducting path interconnecting upper and bottom electrodes are transformed into tetrahedron structures. In order to set the filamentary conducting path back to the low resistance state, it is necessary to newly form an intermediate length conductive path. Therefore, the set voltage of the resistive switching unit 120 becomes higher than the forming voltage. Oxygen atoms required for the forming process, the set process, and the reset process are provided from the first electrode 130 including an oxide electrode.

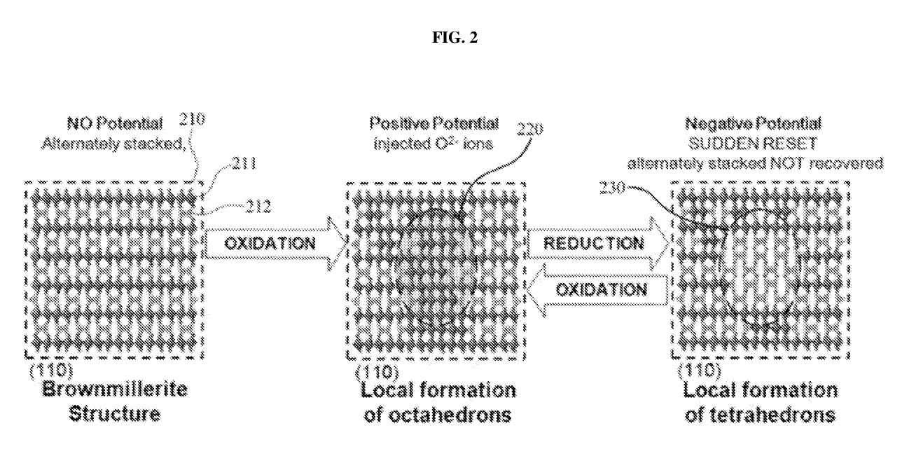

In other words, the resistive switching unit 120, which is a brownmillerite-structured insulator, obtains a conductive structure as a phase transition occurs due to a forming voltage applied by the first electrode 130 and the second electrode 110. Furthermore, through a reset process for switching the resistive switching unit 120 to a high resistance state, not only octahedron structures transformed from tetrahedron structures by the forming process, but also layers having original octahedron structures existing before the forming process are transformed to tetrahedron structures. Therefore, during a set process for switching the resistive switching unit 120 back to the low resistant state, all of local portions transformed to tetrahedron structures are transformed to octahedron structures, and therefore, a set voltage becomes higher than the forming voltage. A phase transition phenomenon caused by a redox reaction in the forming process, the set process, and the reset process of the resistive switching unit 120 will be described below in detail with reference to FIG. 2.

The material constituting the resistive switching unit 120 is a brownmillerite-structured oxide and strontium cobalt (SrCoOₓ) and strontium ferrite (SrFeOₓ) may be utilized. Furthermore, other brownmillerite-structured oxides may also be used.

FIG. 2 is a diagram showing a phase transition phenomenon of a resistive switching memory device using a brownmillerite-structured material according to an embodiment of the present invention.

Referring to FIGS. 1 and 2, a brownmillerite structure 210 of the resistive switching unit 120 has a structure in which an octahedron structure layer 211 and a tetrahedron structure layer 212 are alternately, vertically grown and stacked layer by layer. The tetrahedron structure layer 212 has a phase in which some of oxygen (O) atoms are removed from the octahedron structure layer 211.

A conductive Perovskite material having an octahedron structure loses its electrical conductivity when only one octahedron structure layer is independently present, and may exhibit electrical conductivity when at least three to ten octahedron structured layers are successively coupled to each other. The brownmillerite structure 210 of the resistive switching unit 120 (SrCoO_{2.5}) including the alternately stacked octahedron structure layer 211 and the tetrahedron structure layer 212 exhibits an electrical insulation characteristic. When a forming voltage is applied to the brownmillerite structure 210 of the resistive switching unit 120, a phase transition of the brownmillerite structure 210 by an oxidation reaction occurs, and therefore oxygen atoms supplied from the first electrode 130 forms a local partial octahedron deformed region 220 in which some tetrahedron structures of the tetrahedron structure layer 212 are transformed into octahedron structures. This process is referred to as a forming process. Since the octahedron structure layer 211 is successively coupled to each other from the top electrode to the bottom electrode through the local partial octahedron deformed region 220 formed in the brownmillerite structure 210 of the resistive switching unit 120 in the forming process, the resistive switching unit 120 becomes a low resistance state having electrical conductivity. The resistive switching unit 120 having the local partial octahedron deformed region 220 enables electrical conduction between the first electrode 130 and the second electrode 110 as a conductive path.

A reset process is a process for switching the resistive switching unit 120 from a low resistance state to a high resistance state. When a reset voltage is applied to the resistive switching unit 120 having a local partial octahedron deformed region 220 highlighted in yellow, a reduction reaction is initiated.

The reset process is not sequentially performed in an order reverse to the order of the forming process. The local partial octahedron deformed region 220 formed in the forming process is not completely transformed to the brownmillerite structure 210 in the reset process. Rather, the reset process occurs very dynamically and rapidly. In other words, through the reset process, the resistive switching unit 120 does not return to the brownmillerite structure 210 existing previously to the forming process. Rather, the resistive switching unit 120 is transformed to a structure in which significant portion of the region highlighted in yellow became a local partial tetrahedron deformed region 230. As oxygen atoms are simultaneously removed from local regions during the reset process, a portion of the original octahedron structure in the brownmillerite structure 210 existing before the forming process is also transformed into a tetrahedron structure, and thus the local partial tetrahedron deformed region 230 is formed. Therefore, the local partial tetrahedron deformed region 230 has no octahedron structure and only tetrahedron structures remain therein. As a result, a conductive path formed during the forming process becomes broken by the local partial tetrahedron deformed region 230, and thus the resistive switching unit 120 is switched to a high resistance state.

The resistive switching unit 120, which is switched a high resistance state due to the local partial tetrahedron deformed region 230, is switched back to a low resistance state through a set process. When a set voltage is applied to the resistive switching unit 120 having the local partial tetrahedron deformed region 230, the local partial tetrahedron deformed region 230 is oxidized again and is transformed into the local partial octahedron deformed region 220. As a result, the resistive switching unit 120 is switched from the high resistance state back to the low resistance state. The local partial tetrahedron deformed region 230 is referred to a region including a portion that was the tetrahedron structure portion before forming process and is transformed into an octahedron structure and an adjacent portion that was an octahedron structure existing before the forming process.

In the forming process, since the tetrahedron structure layers 212 between the octahedron structure layers 211 are formed to be the local partial octahedron deformed region 220, very short conductive paths are sequentially connected to each other. On the contrary, in the set process, the local partial tetrahedron deformed region 230 is transformed into the local partial octahedron deformed region 220. Therefore, since a conductive path to be oxidized in the forming process is shorter than that in the set process, a forming voltage becomes lower than a set voltage.

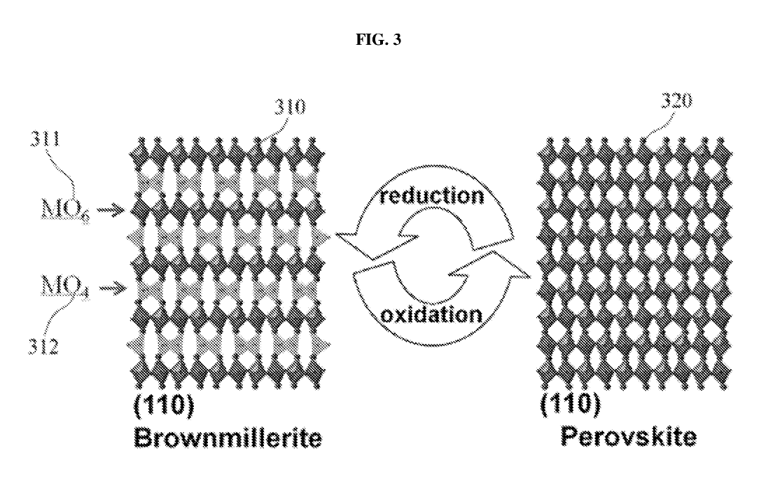

FIG. 3 is a diagram showing an example of a resistive switching unit using SrCoOₓ for a resistive switching memory device that uses a brownmillerite-structured material according to an embodiment of the present invention.

Referring to FIG. 3, strontium cobalt oxide (SrCoOₓ) may be used as a resistive switching unit in a resistive switching memory device using a brownmillerite-structured material according to an embodiment of the present invention. SrCoOₓ is a material in which phase transition occurs at a relative ease. Particularly, phase transition occurs relatively easily via a redox reaction between SrCoO₃ which includes octahedron structures and exhibits electric conductivity, and SrCoO_{2.5} which has a brownmillerite structure.

In order to switching SrCoO_{2.5} having an insulator brownmillerite structure from a high resistance state 310 of an initial insulation stage to a low resistance state 320, oxygen atoms may be injected (for oxidization) to one tetrahedron structure layer (MO₄) 312 between two octahedron structure layers (MO₆) 311 that are very close to each other without contacting each other. In the SrCoO_{2.5}, each thickness of the octahedron structure layer and tetrahedron structure layer is about 0.2 nm. By repeating this process between respective corresponding layers, a first electrode and a second electrode may be electrically connected (320) to each other through the octahedron structure layers and exhibit conductivity. In other words, by sequentially oxidizing only the tetrahedron structure layers between the octahedron structure layers, the brownmillerite structure 310 of SrCoO_{2.5} is partially transformed into a Perovskite structure 320, thereby forming a conductive path in the strontium cobalt oxide. In a conventional resistive switching device, it is necessary to transform a relatively long conductive path interconnecting a top electrode and a bottom electrode at once. On the contrary, in case of the SrCoO_{2.5}, since a conductive path may be established by transforming only tetrahedron structure layers between octahedron structure layers, the SrCoO_{2.5} may have a forming voltage lower than that of the conventional resistive switching device.

SrCoO_{2.5}+xO²⁻ [symbol] SrCoO_{2.5+x}+2xe⁻ [Reaction equation 1]

Reaction equation 1 describes oxidation/reduction reactions between the brownmillerite structure 310 and the Perovskite structure 320. In Reaction equation 1, x represents a value that amounts to approximately 0.5. The SrCoO_{2.5} establishes and breaks a conductive path through oxidation and reduction reactions as shown in Reaction equation 1.

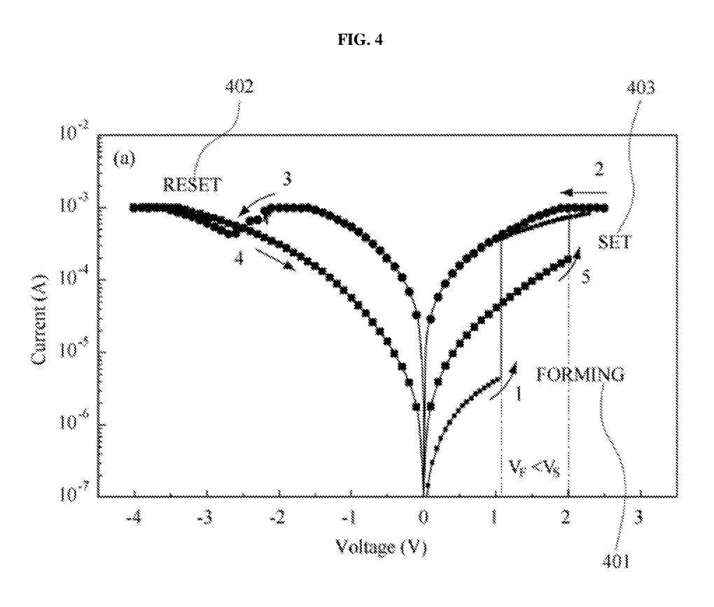

FIG. 4 is a diagram showing a forming voltage, a set voltage, and a reset voltage of a resistive switching memory device using a brownmillerite-structured material according to an embodiment of the present invention.

Referring to FIG. 4, strontium cobalt oxide (SrCoOₓ) may be used as a resistive switching unit for a resistive switching memory device using a brownmillerite-structured material according to an embodiment of the present invention, as shown in FIG. 3. The SrCoOₓ is a material in which phase transition occurs at a relative ease. Particularly, phase transition occurs easily via redox reaction between SrCoO₃ which includes octahedron structures and exhibits electric conductivity, and SrCoO_{2.5} which has a brownmillerite structure.

In order to switch the SrCoO_{2.5} having an insulating brownmillerite structure from the initial insulation state to the low resistance state 320, oxygen atom may be injected (for oxidation) to a tetrahedron structure layer between the octahedron structure layers, which do not contact each other but are very close to each other. In the SrCoO_{2.5}, thickness of each of the octahedron structure layer and tetrahedron structure layer is about 0.2 nm. By repeating this process between respective corresponding layers, a first electrode and a second electrode may be electrically connected (320) to each other through the octahedron structure layers, thereby obtaining a conductivity. In a conventional resistive switching device, it is necessary to transform a relatively long conductive path interconnecting a top electrode and a bottom electrode at once. On the contrary, in case of the SrCoO_{2.5}, since a conductive path may be established by transforming only tetrahedron structure layers between octahedron structure layers, the SrCoO_{2.5} may have a forming voltage lower than that of the conventional resistive switching device. In the forming process, a forming voltage 401 gradually increases, and then when a tetrahedron structure layer is oxidized to an octahedron structure layer and the bottom electrode and the top electrode are connected to each other through the octahedron structure layer, the forming voltage 401 rapidly increases.

The SrCoO_{2.5} that is switched to a low resistance state through the forming process is switched back to a high resistance state by a reset process using a reset voltage 402. The reset process in which an octahedron structure is transformed back to a tetrahedron structure through a reduction process that removes oxygen from the octahedron structure occurs not in a sequential manner, but occurs in a local region at once. Therefore, a portion of the original octahedron structure layer in the transformed local region is also transformed into a tetrahedron structure in the reset process. As a result, through the reset process, the conductive path is partially broken, and thus a local partial tetrahedron deformed region is formed, where octahedron structures disappear in the local partial tetrahedron deformed region.

The SrCoO_{2.5}, which is switched to the high resistance state through the reset process, may be switched back to the low resistance state again by the set process. In the reset process, the local partial tetrahedron deformed region is transformed into an octahedron structure again when the set voltage is applied, thereby establishing a conductive path. The forming voltage 401 transforms only the tetrahedron structure layer between the octahedron structure layers into the octahedron structure layer, but it is required to transform the local partial tetrahedron deformed region to octahedron structures simultaneously in the set process. In other words, vertical height of a tetrahedron structure in the local partial tetrahedron deformed region may not be 0.2 nm as in a brownmillerite structure in an initial state, but amount to several tens to several hundred times of 0.2 nm. Since it is required to establish conductive paths longer than those in the forming process, the set voltage 403 becomes greater than the forming voltage 401. As described above, the fact that a forming voltage is lower than the set voltage in a resistive switching memory device using a brownmillerite-structured material according to the present invention is preferable for the application of the resistive switching device. A forming voltage lower than the set voltage provides new advantages for RAM (Random Access Memory) applications due to ease of performing a forming process.

FIG. 5 is a diagram for comparing a forming voltage and a set voltage of a resistive switching memory device using a brownmillerite-structured material according to an embodiment of the present invention to a conventional resistive switching memory device.

Referring to FIG. 5, when a conventional resistive switching memory device 510 generates a conductive path 513 between a top electrode 511 and a bottom electrode 512 through a forming process, the conductive path 513 interconnects the top electrode 511 and the bottom electrode 512. The conventional resistance-switching memory device 510 breaks a portion of a filament constituting the conductive path 513 through a reset process to form a broken conductive path 514. The conventional resistance-switching memory device 510 is in a high resistance state (HRS) due to the broken conductive path 514. Next, the broken conductive path 514 is recovered again by a set process and an entire portion of the conventional resistance-switching memory device 510 between the top electrode 511 and the bottom electrode 512 is connected through the conductive path 513. In this regard, the conventional resistive switching memory device 510 connects the entire portion of the conventional resistance-switching memory device 510 between top electrode 511 and the bottom electrode 512 in the forming process. However, only the broken conductive path 514 in is re-connected by the set process. Therefore, in the conventional resistive switching memory device 510, a forming voltage becomes larger than a set voltage.

The resistive switching memory device 520 using a brownmillerite-structured material according to an embodiment of the present invention has a structure in which octahedron structures and tetrahedron structures are alternately stacked. Therefore, the resistive switching memory device 520 using the brownmillerite-structured material transforms only the tetrahedron structure layer located between the octahedron structure layers to an octahedron structure, thereby forming an octahedron structured conductive path 521. Next, during a reset process, a portion of the octahedron structured conductive path 521 is transformed into a tetrahedron structure, and thus a partial tetrahedron deformed region 522 is formed. Therefore, the resistive switching memory device 520 becomes a high resistance state. Next, in the high resistance state, the partial tetrahedron deformed region 522 is transformed back to a conductive path having an octahedron structure through a set process. As described above, in the resistive switching memory device 520 using a brownmillerite-structured material according to an embodiment of the present invention, only a tetrahedron structure layer between octahedron structured layers is transformed in the forming process, whereas the partial tetrahedron deformed region 522 is transformed to an octahedron structure in the set process. Therefore, since the length of a conductive path to be connected in the set process is longer than that of the forming process, a forming voltage is lower than a set voltage.

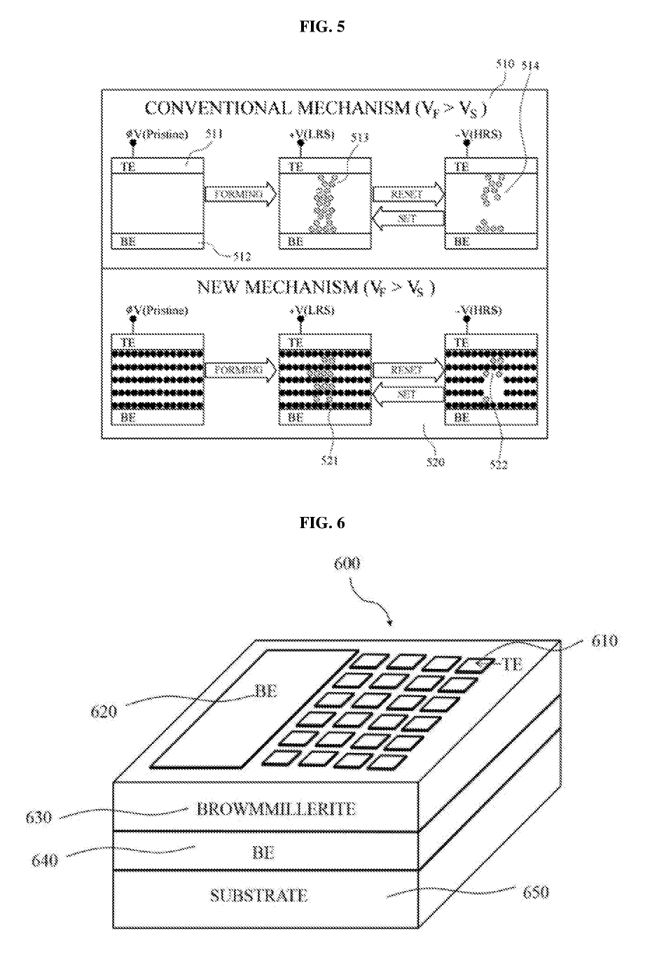

FIG. 6 is a diagram showing another example of a resistive switching memory device using a brownmillerite-structured material according to an embodiment of the present invention.

Referring to FIG. 6, another example resistive switching memory device 600 using a brownmillerite-structured material according to an embodiment of the present invention includes a first electrode 640 which is a bottom electrode including an oxide electrode, a resistive switching unit 630 disposed on the first electrode 640, a second electrode 620 which is disposed on the resistive switching unit 630, penetrates through the resistive switching unit 630, and is connected to the first electrode 640, and a third electrode 610 located on the resistive switching unit 630.

The first electrode 640 is an oxide electrode having the same function as the first electrode 130 of FIG. 1 and may include SrRuO3. The resistive switching unit 630 has the same brownmillerite structure as that of the resistive switching unit shown in FIGS. 1 to 6. The second electrode 620 penetrates through the resistive switching unit 630, is connected to the first electrode 640, and serves as a bottom electrode. Furthermore, the third electrode 610 is a top electrode. The resistive switching memory device using a brownmillerite-structured material according to the embodiment of FIG. 6 is another embodiment of the resistive switching memory device 100 using a brownmillerite-structured material shown in FIG. 1, where performances and purposes are identical to each other.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A resistive switching memory device using a brownmillerite-structured material, the resistive switching memory device comprising:
a first electrode including an oxide electrode;
a resistive switching unit that is disposed on the first electrode and comprises a thin film of a brownmillerite structured oxide; and
a second electrode that is disposed on the resistive switching unit.

2. The resistive switching memory device of claim 1, wherein the resistive switching unit comprises an octahedron structure layer and a tetrahedron structure layer which are sequentially stacked.

3. The resistive switching memory device of claim 2, wherein, in the resistive switching unit, a predetermined portion of the tetrahedron structure layer is transformed to an octahedron structure by an oxidization reaction which occurs by a forming voltage applied to between the first electrode and the second electrode, thereby forming a partial octahedron deformed region.

4. The resistive switching memory device of claim 3, wherein the partial octahedron deformed region forms a conductive path between the first electrode and the second electrode, thereby switching the resistive switching unit into a low resistance state.

5. The resistive switching memory device of claim 3, wherein, in the resistive switching unit having formed therein the partial octahedron deformed region, a partial tetrahedron deformed region is formed by a reduction reaction that occurs based on a reset voltage applied between the first electrode and the second electrode.

6. The resistive switching memory device of claim 5, wherein the partial tetrahedron deformed region transforms the partial octahedron deformed region to a tetrahedron structure and breaks a conductive path between the first electrode and the second electrode, thereby switching the resistive switching unit into a high resistance state.

7. The resistive switching memory device of claim 5, wherein, in the resistive switching unit having formed therein the partial tetrahedron deformed region, the partial tetrahedron deformed region is transformed to the partial octahedron deformed region through an oxidization reaction that occurs based on a set voltage applied between the first electrode and the second electrode.

8. The resistive switching memory device of claim 5, wherein the forming voltage is always lower than the set voltage.

9. The resistive switching memory device of claim 1, wherein the resistive switching unit comprises any one of strontium cobalt oxide (SrCoOₓ) and strontium ferrite (SrFeOₓ).

10. A resistive switching memory device using a brownmillerite-structured material, the resistive switching memory device comprising:
a first electrode disposed on top of a substrate;
a resistive switching unit disposed on top of the first electrode and comprises a thin film of a brownmillerite structured oxide; and
a second electrode disposed on top of the resistive switching unit.

11. The resistive switching memory device of claim 10, wherein the resistive switching unit comprises an octahedron structure layer and a tetrahedron structure layer which are sequentially stacked.

12. The resistive switching memory device of claim 11, wherein, in the resistive switching unit, a predetermined portion of the tetrahedron structure layer is transformed to an octahedron structure by an oxidization reaction which occurs by a forming voltage applied to between the first electrode and the second electrode, thereby forming a partial octahedron deformed region.

13. The resistive switching memory device of claim 12, wherein the partial octahedron deformed region forms a conductive path between the first electrode and the second electrode, thereby switching the resistive switching unit into a low resistance state.

14. The resistive switching memory device of claim 12, wherein, in the resistive switching unit having formed therein the partial octahedron deformed region, a partial tetrahedron deformed region is formed by a reduction reaction that occurs based on a reset voltage applied between the first electrode and the second electrode.

15. The resistive switching memory device of claim 14, wherein the partial tetrahedron deformed region transforms the partial octahedron deformed region to a tetrahedron structure and breaks a conductive path between the first electrode and the second electrode, thereby switching the resistive switching unit into a high resistance state.

16. The resistive switching memory device of claim 14, wherein, in the resistive switching unit having formed therein the partial tetrahedron deformed region, the partial tetrahedron deformed region is transformed to the partial octahedron deformed region through an oxidization reaction that occurs based on a set voltage applied between the first electrode and the second electrode.

17. The resistive switching memory device of claim 14, wherein the forming voltage is always lower than the set voltage.

18. The resistive switching memory device of claim 10, wherein the resistive switching unit comprises any one of strontium cobalt oxide (SrCoOₓ) and strontium ferrite (SrFeOₓ).
